(19) United States
(12) Patent Application Publication
(10) Pub. No.: US 2026/0023114 A1
(43) Pub. Date: Jan. 22, 2026

(54) SEMICONDUCTOR INTEGRATED CIRCUIT

(71) Applicant: ROHM CO., LTD., Kyoto (JP)

(72) Inventors: Kenji YAMADA, Kyoto (JP); Koichi MIYANAGA, Kyoto (JP)

(21) Appl. No.: 19/263,652

(22) Filed: Jul. 9, 2025

(30) Foreign Application Priority Data
Jul. 16, 2024 (JP) 2024-113579

(51) Int. Cl. G01R 31/3185

(52) U.S. Cl. CPC G01R 31/318544; G01R 31/318583

(57) ABSTRACT

A semiconductor integrated circuit includes a test target circuit which is subjected to a scan test and configured to generate an output signal for controlling an operation of an analog circuit in response to an input signal, a test controller for controlling the scan test in the test target circuit, and a holder for holding the output signal. When the analog circuit is in an active state, the test controller executes the scan test on the test target circuit in response to a signal requesting execution of the scan test being transmitted to the semiconductor integrated circuit. While the scan test is being executed, the holder holds the output signal available after the signal is transmitted to the semiconductor integrated circuit and before the scan test begins, and outputs the held output signal so as to keep the analog circuit in the active state.

### CROSS-REFERENCE TO RELATED APPLICATION

The present invention claims priority under 35 U.S.C. § 119 to Japanese Patent Application No. 2024-113579, filed on Jul. 16, 2024, the entire contents of which are incorporated herein by reference.

### TECHNICAL FIELD

The present disclosure relates to a semiconductor integrated circuit.

### BACKGROUND

In the related art, a scan test for diagnosing a fault in a logic circuit or the like of a digital circuit is known. In the related art, there is disclosed a semiconductor integrated circuit including a logic circuit and a plurality of scan flip-flop circuits capable of forming a scan chain for performing a scan test on the logic circuit.

### BRIEF DESCRIPTION OF DRAWINGS

The accompanying drawings, which are incorporated in and constitute a part of the specification, illustrate embodiments of the present disclosure.

FIG. 1 is a block diagram of a semiconductor integrated circuit according to a first embodiment.

FIG. 2 is a block diagram of a digital block according to the first embodiment.

FIG. 3 is a block diagram of a test target circuit according to the first embodiment.

FIG. 4 is a block diagram for explaining exemplary configurations of a test target circuit, a first holder, a second holder, and an output selector.

FIG. 5 is a diagram showing an example of a circuit configuration of a scan flip-flop circuit.

FIG. 6 is a timing chart of each voltage in the semiconductor integrated circuit according to the first embodiment.

FIG. 7 is a flowchart showing an example of a process until a scan test is executed in the digital block according to the first embodiment.

FIG. 8 is a flowchart showing an example of a process until an operation of the digital block returns to a normal operation after the scan test is executed in the digital block according to the first embodiment.

FIG. 9 is a flowchart showing an example of a flow of a scan test process according to the first embodiment.

FIG. 10 is a block diagram of a digital block according to a second embodiment.

FIG. 11 is a diagram for explaining a process in which a third holder according to the second embodiment acquires internal data of the test target circuit and a process in which the third holder returns the internal data to the test target circuit.

FIG. 12 is a flowchart showing an example of a process until the scan test is executed in the digital block according to the second embodiment.

FIG. 13 is a flowchart showing an example of a process until an operation of the digital block returns to a normal operation after the scan test is executed in the digital block according to the second embodiment.

FIG. 14 is a block diagram for explaining a first holder according to a first modification.

FIG. 15 is a block diagram of a second holder according to a second modification.

### DETAILED DESCRIPTION

### (Overview)

An overview of some exemplary embodiments of the present disclosure will be described. This overview presents, in a simplified form, some concepts of one or more embodiments, as a prologue to the detailed description which will be presented later, and for the purpose of basic understanding of the embodiments, but it is not intended to limit the scope of the invention or the disclosure. This overview is not a comprehensive overview of all possible embodiments, and it is intended to neither identify key elements of all embodiments nor delineate the scope of some or all aspects. For the sake of convenience in description, “an embodiment” may be used to refer to one embodiment (example or modification) or a plurality of embodiments (examples or modifications) disclosed herein.

A semiconductor integrated circuit according to one embodiment includes a test target circuit, which is a digital circuit to be subjected to a scan test, configured to generate an output signal for controlling an operation of an analog circuit in response to an input signal, a test controller configured to control the scan test in the test target circuit, and a holder configured to hold the output signal. When the analog circuit is in an active state, the test controller executes the scan test on the test target circuit in response to a signal requesting execution of the scan test being transmitted to the semiconductor integrated circuit. While the scan test is being executed, the holder holds the output signal available after the signal requesting the execution of the scan test is transmitted to the semiconductor integrated circuit and before the scan test begins, and outputs the held output signal so as to keep the analog circuit in the active state.

According to this configuration, by using the output signal output from the holder, it is possible to continue the operation of the analog circuit even while the scan test is being executed on the test target circuit.

In one embodiment, the holder may include a first holder configured to hold the input signal and a second holder configured to hold the output signal. The first holder may hold the input signal corresponding to the output signal held by the second holder while the scan test is being executed.

In one embodiment, the test target circuit may include a plurality of scan flip-flop circuits which forms a scan chain, and logic circuits. Each of the plurality of scan flip-flop circuits may have a test data input terminal to which test data for the scan test is input and a normal data input terminal to which normal data different from the test data is input. Each of the plurality of scan flip-flop circuits may be configured to be switchable between a first mode in which the normal data input terminal is in a valid state and the test data input terminal is in an invalid state, and a second mode in which the normal data input terminal is in an invalid state and the test data input terminal is in a valid state. Each of the first holder and the second holder may be constituted with a scan flip-flop circuit that does not contribute to the scan chain.

In one embodiment, the second holder may include a signal holding circuit constituted with the scan flip-flop circuit that does not contribute to the scan chain. The signal holding circuit may be provided so that the output signal is input to the normal data input terminal and no data is input to the test data input terminal, and is configured to hold the output signal in response to switching from the first mode to the second mode.

In one embodiment, the second holder may include a signal holding circuit constituted with the scan flip-flop circuit that does not contribute to the scan chain, and a multiplexer configured to select one of an output signal of the signal holding circuit and the output signal generated by the test target circuit and input the selected signal to a data input terminal of the signal holding circuit. While the scan test is being executed, the multiplexer may select the output signal of the signal holding circuit such that the output signal generated by the test target circuit is held by the signal holding circuit in the first mode.

In one embodiment, the first holder may include a multiplexer having two input terminals and a signal holding circuit constituted with the scan flip-flop circuit that does not contribute to the scan chain. The multiplexer may be provided so that the input signal is input to a first input terminal of the two input terminals and an output signal of the signal holding circuit is input to a second input terminal of the two input terminals. While the scan test is being executed, the multiplexer may select the output signal of the signal holding circuit such that the output signal is held by the signal holding circuit in the first mode.

In one embodiment, the first holder may include a signal holding circuit constituted with the scan flip-flop circuit that does not contribute to the scan chain. While the scan test is being executed, when a signal having no rising and falling edges is input to a clock input terminal of the signal holding circuit, the signal holding circuit may hold the input signal.

In one embodiment, the semiconductor integrated circuit may further include an output selector configured to select one of the output signal generated by the test target circuit and the output signal held by the holder, and output the selected signal. While the scan test is being executed, the output selector may select the output signal held by the holder.

In one embodiment, the semiconductor integrated circuit may further include a communication interface configured to receive the signal requesting the execution of the scan test. The test target circuit may include the communication interface.

In one embodiment, the semiconductor integrated circuit may further include a state controller configured to control a state of the test target circuit. The state controller may cause the test target circuit to execute a predetermined process so that the test target circuit is capable of generating the output signal for keeping the analog circuit in the active state after the scan test is completed.

In one embodiment, the semiconductor integrated circuit may further include a third holder configured to hold internal data of the test target circuit. The internal data may be constituted with internal signals of the plurality of scan flip-flop circuits forming the scan chain. The third holder may acquire internal data corresponding to the output signal held by the second holder from the scan chain, and hold the acquired internal data. After the scan test is completed, the internal data held by the third holder may be returned to the scan chain.

In one embodiment, the semiconductor integrated circuit may further include a determiner configured to determine whether or not a result of the scan test is pass or fail, and a communication interface configured to transmit a determination result indicating that the result of the scan test is fail when the determiner determines that the result of the scan test is fail.

In one embodiment, the analog circuit may constitute a DC voltage converter. The active state may be a state in which the DC voltage converter outputs a predetermined voltage.

### EMBODIMENTS

Preferred embodiments will now be described with reference to the drawings. Like or equivalent components, members, and processes illustrated in each drawing are given like reference numerals and a repeated description thereof will be properly omitted. Further, the embodiments are presented by way of example only and are not intended to limit the present disclosure and invention, and any features or combination thereof described in the embodiments may not necessarily be essential to the present disclosure and invention.

In this specification, the expression “a member A is connected to a member B” includes not only a case where the member A and the member B are physically directly connected to each other, but also a case where the member A and the member B are indirectly connected to each other via any other member that does not substantially affect an electrical connection state between the members A and B or does not impair functions and effects achieved by combinations of the members A and B.

Similarly, the expression “a member C is connected (installed) between a member A and a member B” includes not only a case where the member A and the member C or the member B and the member C are directly connected to each other, but also a case where the member A and the member C or the member B and the member C are indirectly connected to each other via any other member that does not substantially affect an electrical connection state between the members A and C or the members B and C or does not impair functions and effects achieved by combinations of the members A and C or the members B and C.

Further, in the present disclosure, symbols attached to electrical signals such as voltage signals and current signals, or circuit elements such as resistors, capacitors, and inductors, represent respective voltage values, current values, or circuit constants (resistance, capacitance, and inductance) as necessary.

Further, in the present disclosure, the term “integrated” includes a case where all of constituent elements of a circuit are formed on a semiconductor substrate and a case where main constituent elements of the circuit are integrated, and some resistors, capacitors, and the like may be provided outside the semiconductor substrate for adjusting circuit constants.

### First Embodiment

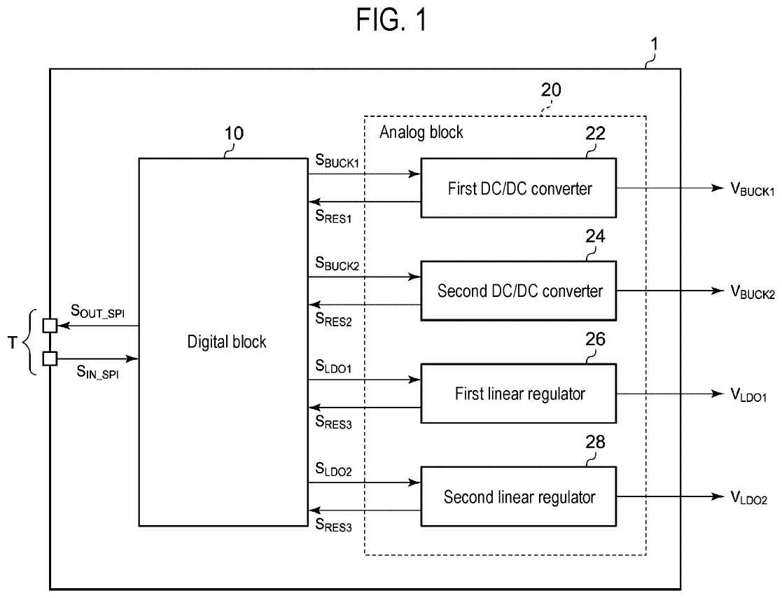

FIG. 1 is a block diagram of a semiconductor integrated circuit 1 according to a first embodiment. The semiconductor integrated circuit 1 according to this embodiment is a power management integrated circuit (PMIC) for a vehicle. The semiconductor integrated circuit 1 is not limited to the PMIC, and may be an integrated circuit capable of implementing various functions. The semiconductor integrated circuit 1 according to this embodiment includes a digital block 10, an analog block 20, and input/output pins T.

The digital block 10 includes various digital circuits. The digital block 10 according to this embodiment executes various processes while transmitting and receiving various signals via the input/output pins T. The digital block 10 receives an input signal S_{IN_SPI} and transmits an output signal S_{OUT_SPI} by, for example, a serial peripheral interface (SPI) communication.

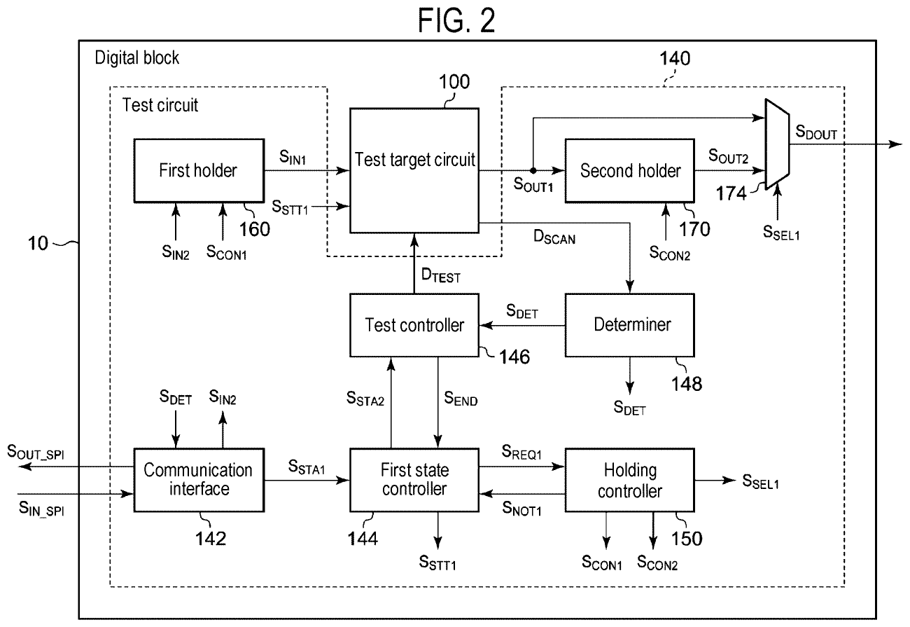

The digital block 10 generates digital output signals S_{BUCK1}, S_{BUCK2}, S_{LDO1} and S_{LDO2} required for respective analog circuits in the analog block 20, and executes a built-in self-test (BIST), specifically a scan test. A detailed configuration of the digital block 10 will be described later with reference to FIG. 2, or the like.

The analog block 20 includes various analog circuits. In this embodiment, the analog block 20 includes a plurality of DC voltage converters. These DC voltage converters convert a voltage generated by a primary power supply (not shown) according to a power supply voltage supplied from a system battery (or a voltage obtained by stepping down this voltage) to generate a DC voltage. The generated DC voltage may be supplied to, for example, a micro-controller unit (MCU) for a vehicle, or the like.

The DC voltage converter according to this embodiment includes a first DC/DC converter 22, a second DC/DC converter 24, a first linear regulator 26, and a second linear regulator 28. In this embodiment, an example will be described in which the first DC/DC converter 22 and the second DC/DC converter 24 are step-down DC/DC converters, and the first linear regulator 26 and the second linear regulator 28 are low-dropout (LDO) linear regulators.

The first DC/DC converter 22, the second DC/DC converter 24, the first linear regulator 26, and the second linear regulator 28 receive the digital output signals S_{BUCK1}, S_{BUCK2}, S_{LDO1} and S_{LDO2} from the digital block 10, respectively, and generate output voltages V_{BUCK1}, V_{BUCK2}, V_{LDO1} and V_{LDO2}, respectively. The first DC/DC converter 22, the second DC/DC converter 24, the first linear regulator 26, and the second linear regulator 28 may transmit response signals S_{RES1}, S_{RES2}, S_{RES3} and S_{RES4} indicating their states, respectively, to the digital block 10 as necessary.

FIG. 2 is a block diagram of the digital block 10 according to the first embodiment. The digital block 10 includes various digital circuits, specifically, a test target circuit 100 which is a digital circuit to be subjected to a scan test, and a test circuit 140 which performs a process relating to the scan test. In this embodiment, the test circuit 140 is not subject to the scan test.

The test target circuit 100 generates an output signal S_{OUT1} for controlling an operation of the analog circuit in response to an input signal S_{IN1}. The test target circuit 100 executes various processes in response to a state control signal S_{STT1} to generate an output signal S_{OUT1} corresponding to the input signal S_{IN1}, and outputs scan data D_{SCAN} in response to test data D_{TEST}. The output signal S_{OUT1} generated by the test target circuit 100 is input to a second holder 170 and an output selector 174, which will be described later.

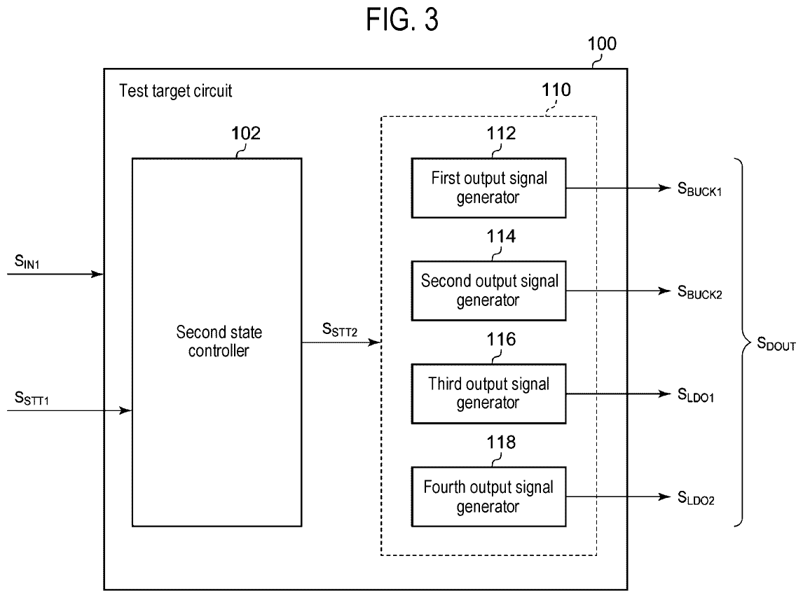

FIG. 3 is a block diagram of the test target circuit 100 according to the first embodiment. The test target circuit 100 includes a second state controller 102 and an output signal generator 110.

The second state controller 102 controls a state of the test target circuit 100 based on the state control signal S_{STT1}. For example, the second state controller 102 transmits a state control signal S_{STT2} to the output signal generator 110 and causes the output signal generator 110 to generate an output signal S_{DOUT} so that the analog circuit is in an active state.

The output signal generator 110 according to this embodiment includes a first output signal generator 112, a second output signal generator 114, a third output signal generator 116, and a fourth output signal generator 118. The first output signal generator 112, the second output signal generator 114, the third output signal generator 116, and the fourth output signal generator 118 output output signals S_{BUCK1}, S_{BUCK2}, S_{LDO1} and S_{LDO2}, respectively. The output signals S_{BUCK1}, S_{BUCK2}, S_{LDO1} and S_{LDO2} constitute the output signal S_{DOUT} of the test target circuit 100.

Returning to FIG. 2, a configuration and functions of the test circuit 140 will be described. The test circuit 140 includes a communication interface 142, a first state controller 144, a test controller 146, a determiner 148, a holding controller 150, a first holder 160, a second holder 170, and an output selector 174.

The communication interface 142 transmits and receives various signals. The communication interface 142 according to this embodiment receives an input signal S_{IN_SPI} and transmits an output signal S_{OUT_SPI} by the SPI communication. The input signal S_{IN_SPI} may include, for example, a signal requesting execution of the scan test (hereinafter, also referred to as a “test request signal”), an input signal of the test target circuit 100, and the like. The output signal S_{OUT_SPI} may be, for example, a signal indicating a result of the scan test (e.g., a fail result). The communication interface 142 may transmit a test request signal S_{STA1} to the first state controller 144 and transmit an input signal S_{IN2} of the test target circuit 100 to the first holder 160.

The communication interface 142 may receive the test request signal from an MCU (not shown), for example, when all the analog circuits in the analog block 20 are in the active state. As used herein, the term “active state” refers to a state in which the functions that the analog circuits should perform are implemented. For example, when the analog circuits constitute a DC voltage converter, the active state refers to a state in which the DC voltage converter generates a predetermined output voltage and supplies the generated output voltage to another large scale integration (LSI) or the like.

For example, in the case of a step-down DC/DC converter, when the output voltage generated by stepping down the input voltage falls within a predetermined voltage range, the DC/DC converter may be in the active state. Similarly, in the case of a linear regulator, when the generated output voltage falls within a predetermined voltage range, the linear regulator may be in the active state.

The first state controller 144 controls a state of the test target circuit 100 and transmits signals relating to the scan test. For example, the first state controller 144 transmits a state control signal S_{STT1} to the test target circuit 100 to control the state of the test target circuit 100. The first state controller 144 may also transmit a test request signal S_{STA2} to the test controller 146. Further, the first state controller 144 may transmit, to the holding controller 150, a request signal S_{REQ1} that requests the first holder 160 to hold the input signal S_{IN2} and the second holder 170 to hold the output signal S_{OUT1} generated by the test target circuit 100.

After the scan test is completed, the first state controller 144 may cause the test target circuit 100 to execute a predetermined process so that the test target circuit 100 generates the output signal S_{OUT1} for putting the analog circuit into the active state. Once the scan test is executed, the internal data of the test target circuit 100 is changed. In this state, even if the input signal S_{IN1} is input to the test target circuit 100, an appropriate output signal S_{OUT1} is not generated. Therefore, in this embodiment, after the scan test is completed, the test target circuit 100 is caused to execute a process that is executed when the semiconductor integrated circuit 1 starts up. As a result, the internal data of the test target circuit 100 is brought into a state suitable for generating the output signal S_{OUT1} for putting the analog circuit into the active state, and the test target circuit 100 may generate an appropriate output signal S_{OUT1} in response to the input signal S_{IN1}.

The test controller 146 controls the scan test in the test target circuit 100. Specifically, the test controller 146 transmits test data D_{TEST} to the test target circuit 100 so that the test target circuit 100 outputs scan data D_{SCAN}. Once the scan test is completed, the test controller 146 may transmit a signal SEND indicating that the scan test is completed to the first state controller 144.

When the analog circuit of the analog block 20 is in an active state, the test controller 146 executes the scan test on the test target circuit 100 as the signal requesting the execution of the scan test is transmitted to the semiconductor integrated circuit 1. Specifically, the test controller 146 starts the scan test on the test target circuit 100 in response to receiving a test request signal S_{STA2}.

In this embodiment, the test controller 146 starts the scan test on the test target circuit 100 when all the analog circuits in the analog block 20 (i.e., the first DC/DC converter 22, the second DC/DC converter 24, the first linear regulator 26, and the second linear regulator 28) are in the active state.

The determiner 148 determines whether or not a result of the scan test on the test target circuit 100 is pass or fail. In this embodiment, the determiner 148 determines whether the result is pass or fail based on the scan data D_{SCAN} output from the test target circuit 100. Specifically, the determiner 148 compares the scan data D_{SCAN} with correct answer data DANS which is to be output from the test target circuit 100, and determines whether the result is pass or fail based on the comparison result.

For example, when the scan data D_{SCAN} and the correct answer data DANS match each other, the determiner 148 may determine that the result of the scan test is pass. On the other hand, when the scan data D_{SCAN} and the correct answer data DANS do not match each other, the determiner 148 may determine that the result of the scan test is fail. For example, in a case in which the logic circuit in the test target circuit 100 has a stuck-at fault in which the output is fixed to a high level or a low level, the result of the scan test may be determined to be fail. The determiner 148 may transmit a signal S_{DET} indicating the determination result to the communication interface 142 and the test controller 146.

The holding controller 150 controls the holding of the input signal S_{IN2} by the first holder 160 and the holding of the output signal S_{OUT1} by the second holder 170. Specifically, the holding controller 150 transmits a control signal S_{CON1} to the first holder 160 to cause the first holder 160 to hold the input signal S_{IN2} and to release the input signal S_{IN1} held by the first holder 160. The released input signal S_{IN1} is input to the test target circuit 100.

The holding controller 150 transmits a control signal S_{CON2} to the second holder 170, causing the second holder 170 to hold the output signal S_{OUT1}. Further, when the holding of the signals by the first holder 160 and the second holder 170 is completed, the holding controller 150 may transmit a signal S_{NOT1} notifying such an action to the first state controller 144. In addition, the holding controller 150 may transmit, to the output selector 174, a selection signal S_{SEL1} that determines the signal to be selected by the output selector 174.

In response to the signal requesting the execution of the scan test being transmitted to the semiconductor integrated circuit 1, the holding controller 150 causes the second holder 170 to hold the output signal S_{OUT1} and the first holder 160 to hold the input signal S_{IN2} corresponding to the output signal S_{OUT1} before the scan test is executed. Upon receiving the request signal S_{REQ1}, the holding controller 150 may cause each of the first holder 160 and the second holder 170 to hold a signal. In this regard, the input signal S_{IN2} corresponding to the output signal S_{OUT1} is the input signal S_{IN2} used in the test target circuit 100 to generate the output signal S_{OUT1}.

The second holder 170 holds the output signal S_{OUT1} generated by the test target circuit 100. While the scan test is being executed, the second holder 170 holds the output signal S_{OUT1} after the signal requesting the execution of the scan test is transmitted to the semiconductor integrated circuit 1 and before the scan test begins, and outputs the output signal S_{OUT2} thus held so that the analog circuit may maintain the active state. The output signal S_{OUT2} thus output is input to the output selector 174.

The second holder 170 is constituted with a circuit which is not subjected to the scan test. Therefore, the second holder 170 may hold the output signal S_{OUT2} and may output the output signal S_{OUT2} even while the scan test is being executed. By using this output signal S_{OUT2} in the analog circuit, it is possible to continue the operation of the analog circuit even while the scan test is being executed.

The output selector 174 selects one of the output signal S_{OUT1} generated by the test target circuit 100 and the output signal S_{OUT2} held by the second holder 170, and outputs the selected output signal S_{DOUT}. The output selector 174 selects the output signal S_{OUT2} held by the second holder 170 while the scan test is being executed. This makes it possible to continue the operation of the analog circuit using the output signal S_{DOUT} even while the scan test is being executed.

The first holder 160 holds the input signal S_{IN2}. The first holder 160 according to the present embodiment holds the input signal S_{IN2} corresponding to the output signal S_{OUT2} held by the second holder 170 while the scan test is being executed. As a result, after the scan test is completed, the input signal S_{IN1} to be input to the test target circuit 100 may be input from the first holder 160.

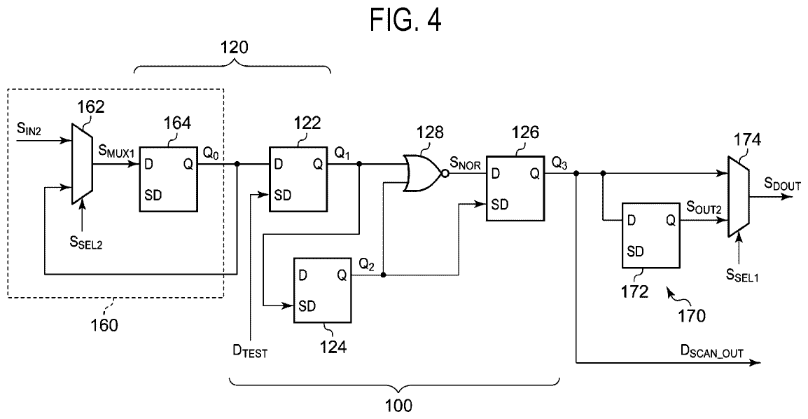

FIG. 4 is a block diagram for explaining exemplary configurations of the test target circuit 100, the first holder 160, the second holder 170, and the output selector 174. The test target circuit 100 is shown in FIG. 4 in a simplified manner.

The test target circuit 100 is constituted by combining a plurality of scan flip-flop circuits and various logic circuits. The test target circuit 100 shown in FIG. 4 includes a plurality of scan flip-flop circuits 122, 124, and 126 which form a scan chain, and a NOR circuit 128. The logic circuit included in the test target circuit 100 is not limited to the NOR circuit, and may be various known logic circuits, for example, an AND circuit, an OR circuit, and a NOT circuit. The test target circuit 100 may also include a plurality of logic circuits. The number of scan flip-flop circuits which form the scan chain is not limited to three, and may be two or four or more.

The scan flip-flop circuits 122, 124, and 126 include a test data input terminal SD to which test data for the scan test is input, and a normal data input terminal D to which normal data different from the test data is input. The scan flip-flop circuits 122, 124, and 126 are configured to be switchable between a capture mode (first mode) in which the normal data input terminal is in a valid state and the test data input terminal is in an invalid state, and a shift mode (second mode) in which the normal data input terminal is in an invalid state and the test data input terminal is in a valid state.

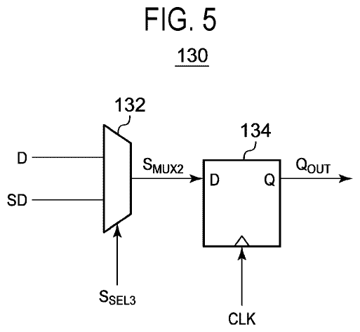

FIG. 5 is a diagram showing an example of a circuit configuration of a scan flip-flop circuit 130. The scan flip-flop circuits 122, 124, and 126 included in the test target circuit 100 and other scan flip-flop circuits shown in this specification have a configuration similar to that of the scan flip-flop circuit 130 shown in FIG. 5.

As shown in FIG. 5, the scan flip-flop circuit 130 according to the present embodiment includes a multiplexer 132 and a D flip-flop 134.

The multiplexer 132 includes an input terminal corresponding to the normal data input terminal and an input terminal corresponding to the test data input terminal. The multiplexer 132 selects a signal input to one of the normal data input terminal and the test data input terminal based on an input selection signal S_{SEL3}, and outputs a selected signal S_{MUX2}. For example, the selection signal S_{SEL3} may be input from the test controller 146 or the holding controller 150. The output signal S_{MUX2} is input to the data input terminal of the D flip-flop 134. The D flip-flop 134 outputs an output signal Q_{OUT} based on the signal S_{MUX2} and the clock signal.

Returning to FIG. 4, the configuration of the test target circuit 100 will be described. The first input terminal of the NOR circuit 128 is connected to the output terminal of the scan flip-flop circuit 122, the second input terminal of the NOR circuit 128 is connected to the output terminal of the scan flip-flop circuit 124, and the output terminal of the NOR circuit 128 is connected to the normal data input terminal of the scan flip-flop circuit 126. When the NOR circuit 128 operates normally, the NOR circuit 128 outputs a signal S_{NOR} obtained by performing a NOR operation on the output signal Q₁ of the scan flip-flop circuit 122 and the output signal Q₂ of the scan flip-flop circuit 124. The output signal Q₃ of the scan flip-flop circuit 126, whose normal data input terminal receives the signal S_{NOR}, becomes the output signal S_{OUT1} of the test target circuit 100 (Q₃=S_{OUT1}).

The output terminal of the scan flip-flop circuit 122 is connected to the test data input terminal of the scan flip-flop circuit 124, and the output terminal of the scan flip-flop circuit 124 is connected to the test data input terminal of the scan flip-flop circuit 126. The three scan flip-flop circuits 122, 124, and 126 form the scan chain in the shift mode.

When the scan chain is formed, the signal of the test data D_{TEST} may be input to the scan flip-flop circuits 122, 124, and 126 by inputting the test data D_{TEST} to the test data input terminal of the scan flip-flop circuit 122. Further, when the scan chain is formed, scan data D_{SCAN} is output from the output terminal of the scan flip-flop circuit 126. The scan data D_{SCAN} is constituted with the output signals Q₁ to Q₃ of the scan flip-flop circuits 122, 124, and 126.

The first holder 160 includes a multiplexer 162 having two input terminals, and a signal holding circuit 164 constituted with a scan flip-flop circuit that does not contribute to the scan chain. The output terminal of the signal holding circuit 164 is connected to the normal data input terminal of the scan flip-flop circuit 122 of the test target circuit 100. The output signal Q₀ of the signal holding circuit 164 is input to the test target circuit 100 as the input signal S_{IN1} (Q₀=S_{IN1}).

The signal holding circuit 164 and the scan flip-flop circuit 122 form a synchronizer constituted with two stages of scan flip-flop circuits. In this embodiment, an example in which the synchronizer is constituted with the two stages of scan flip-flop circuits will be described. However, the synchronizer may be constituted with three or more stages of scan flip-flop circuits. In this case, a first stage of the scan flip-flop circuits may constitute the signal holding circuit, and second and subsequent stages of the scan flip-flop circuits may contribute to the scan chain of the test target circuit.

The multiplexer 162 is provided so that the input signal S_{IN2} is input to one of two input terminals, and the output signal Q₀ of the signal holding circuit 164 is input to the other of the two input terminals. The output terminal of the multiplexer 162 is connected to the normal data input terminal of the signal holding circuit 164. The signal to be selected by the multiplexer 162 may be determined by, for example, a selection signal S_{SEL2} included in the control signal S_{CON1} from the holding controller 150.

When the signal holding circuit 164 holds the input signal S_{IN2}, it is in the capture mode. The multiplexer 162 selects the output signal Q₀ of the signal holding circuit 164 while the scan test is being executed, thereby causing the signal holding circuit 164, which is in the capture mode, to hold the input signal S_{IN2}. When the multiplexer 162 selects the output signal Q₀, the signals S_{MUX1} and Q₀ are looped inside the first holder 160, and the input signal S_{IN2} is held by the signal holding circuit 164.

The second holder 170 includes a signal holding circuit 172 constituted with a scan flip-flop circuit that does not contribute to the scan chain.

The signal holding circuit 172 is provided so that the output signal Q₃ of the test target circuit 100 is input to the data input terminal and no data is input to the test data input terminal. The output signal S_{OUT2} of the signal holding circuit 172 is input to the output selector 174. The signal holding circuit 172 holds the output signal Q₃ in response to switching from the capture mode to the shift mode. Since no data is input to the test data input terminal of the signal holding circuit 172, the internal signal of the signal holding circuit 172 does not change in the shift mode, and the output signal Q₃ may be held.

The output selector 174 is constituted with a multiplexer having two input terminals. One of the two input terminals receives the output signal Q₃ of the test target circuit 100, and the other receives the output signal S_{OUT2} held by the signal holding circuit 172. The signal to be selected by the multiplexer may be determined by the selection signal S_{SEL1} included in the control signal S_{CON2} from the holding controller 150.

In a normal operation, the multiplexer selects the output signal S_{OUT1} (output signal Q₃) generated by the test target circuit 100 in response to the input signal S_{IN1} (output signal Q₀), and outputs the selected output signal S_{DOUT} to the analog circuit. Thus, the analog circuit may operate in response to the input signal S_{IN2}. On the other hand, while the scan test is being executed, the multiplexer selects the output signal S_{OUT2} held by the signal holding circuit 172. Thus, even while the scan test is being executed, the analog circuit may continue to operate based on the output signal S_{OUT1} generated by the test target circuit 100.

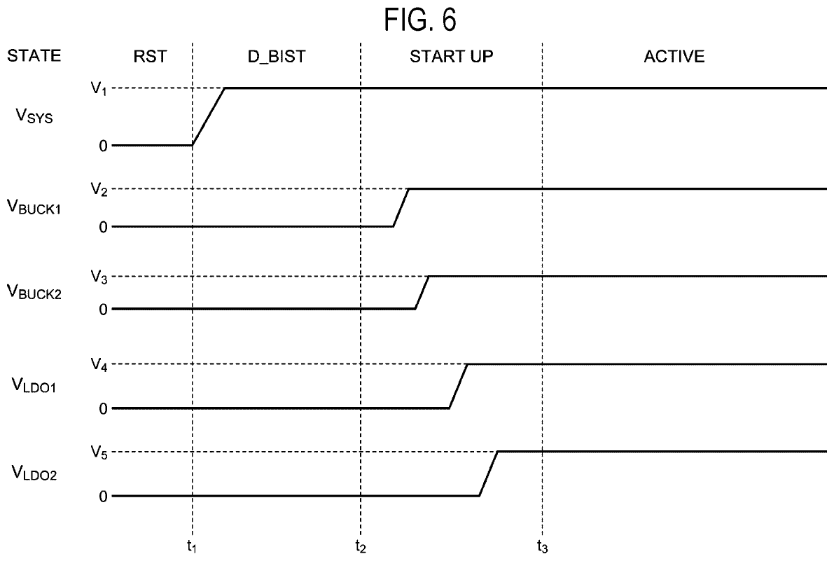

FIG. 6 is a timing chart of each voltage in the semiconductor integrated circuit 1 according to the first embodiment. FIG. 6 shows an output voltage V_{SYS} of the system battery, the output voltage V_{BUCK1} of the first DC/DC converter 22, the output voltage V_{BUCK2} of the second DC/DC converter 24, the output voltage V_{LDO1} of the first linear regulator 26, and the output voltage V_{LDO2} of the second linear regulator 28 sequentially from the top. FIG. 6 shows each of the voltages from when the startup of the semiconductor integrated circuit 1 begins to when all the analog circuits are brought into the active state.

Before timing t1, the semiconductor integrated circuit 1 is in a reset state RST, and all voltages, including the battery output voltage V_{SYS}, are 0 V. At timing t1, the semiconductor integrated circuit 1 starts up, the battery output voltage V_{SYS} rises and reaches a predetermined voltage V1, and a scan test D_BIST is executed on the test target circuit 100. Details of the scan test will be described later.

At timing t2, the scan test is completed, the “START UP” process is performed, and the output voltages of the analog circuits rise in a predetermined order according to the output signal S_{DOUT} of the digital block 10. Until timing t3, the output voltages of all the analog circuits reach predetermined voltages (V2 to V5).

After timing t3, the “ACTIVE” process is performed, and all the analog circuits are set to the active state. In this embodiment, it is possible to perform the scan test again while maintaining all the analog circuits in the active state.

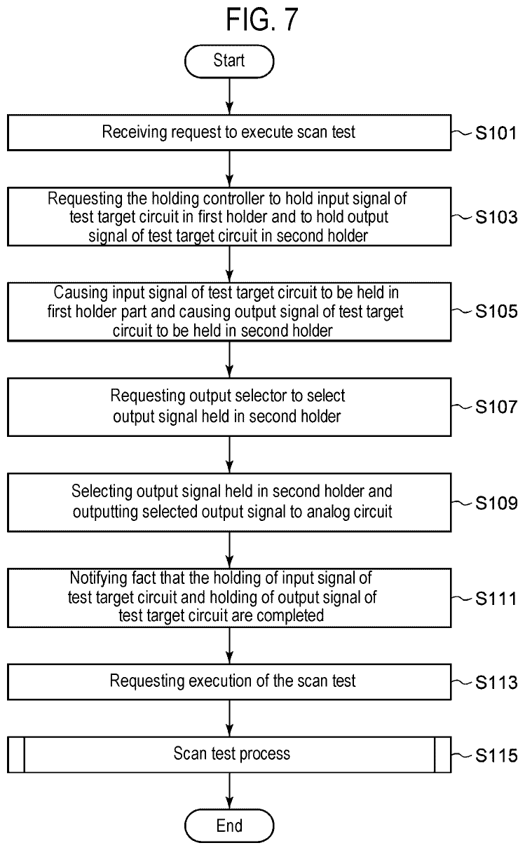

FIG. 7 is a flowchart showing an example of a process until the scan test is executed in the digital block 10 according to the first embodiment. When this process starts, all the analog circuits are assumed to be in the active state. Further, when this process starts, the test target circuit 100, the first holder 160, the second holder 170, and each scan flip-flop circuit of the test target circuit 100 are assumed to be in the capture mode, and the output selector 174 is assumed to have selected the output signal S_{OUT1} generated by the test target circuit 100.

First, the communication interface 142 receives a request to execute the scan test (S101). At this time, the communication interface 142 transmits, to the first state controller 144, a test request signal S_{STA1} indicating that the request to execute the scan test has been received.

Next, the first state controller 144 requests the holding controller 150 to hold the input signal S_{IN2} of the test target circuit 100 in the first holder 160 and to hold the output signal S_{OUT1} of the test target circuit 100 in the second holder 170 (S103). Next, the holding controller 150 causes the input signal S_{IN2} of the test target circuit 100 to be held by the first holder 160 and causes the output signal S_{OUT1} of the test target circuit 100 to be held by the second holder 170 (S105).

Next, the holding controller 150 requests the output selector 174 to select the output signal S_{OUT2} held by the second holder 170 (S107). Next, the output selector 174 selects the output signal S_{OUT2} held by the second holder 170, and outputs the selected output signal S_{DOUT} to the analog circuit (S109). This makes it possible to maintain the analog circuit in the active state using the output signal S_{DOUT} even when the scan test is executed on the analog circuit.

Next, the holding controller 150 notifies the first state controller 144 that the holding of the input signal S_{IN2} by the test target circuit 100 and the holding of the output signal S_{OUT1} by the test target circuit 100 have been completed (S111). Next, the first state controller 144 requests the test controller 146 to execute the scan test (S113). Next, a scan test process is performed (S115).

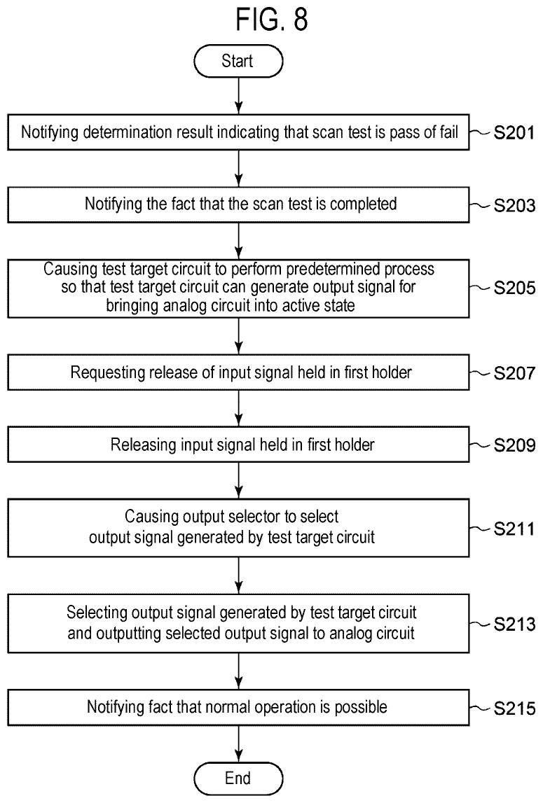

FIG. 8 is a flowchart showing an example of a process in the digital block 10 according to the first embodiment after the scan test is executed and until the operation of the digital block 10 returns to a normal operation.

When the scan test process (S115) is completed, the determiner 148 notifies the test controller 146 of the determination result indicating that the scan test is pass or fail (S201). At this time, when the result of the scan test is fail, the determiner 148 may notify the communication interface 142 of the determination result. Thus, the communication interface 142 may notify externally that the result of the scan test is fail. Next, the test controller 146 notifies the first state controller 144 that the scan test has been completed (S203).

Next, the first state controller 144 causes the test target circuit 100 to execute a predetermined process so that the test target circuit 100 may generate the output signal S_{OUT1} for putting the analog circuit into the active state (S205). In this embodiment, the first state controller 144 causes the test target circuit 100 to execute the “START UP” process and the “ACTIVE” process.

Next, the first state controller 144 requests the holding controller 150 to release the input signal S_{IN1} held by the first holder 160 (S207). Next, the holding controller 150 releases the input signal S_{IN1} held by the first holder 160 (S209). The released input signal S_{IN1} is input to the test target circuit 100. As a result, the test target circuit 100 generates the output signal S_{OUT1} corresponding to the input signal S_{IN1} released from the first holder 160.

Next, the holding controller 150 causes the output selector 174 to select the output signal S_{OUT1} generated by the test target circuit 100 (S211). The output selector 174 selects the output signal S_{OUT1} generated by the test target circuit 100, and outputs the selected output signal S_{DOUT} to the analog circuit (S213). Subsequently, the holding controller 150 notifies that the normal operation is now possible (S215).

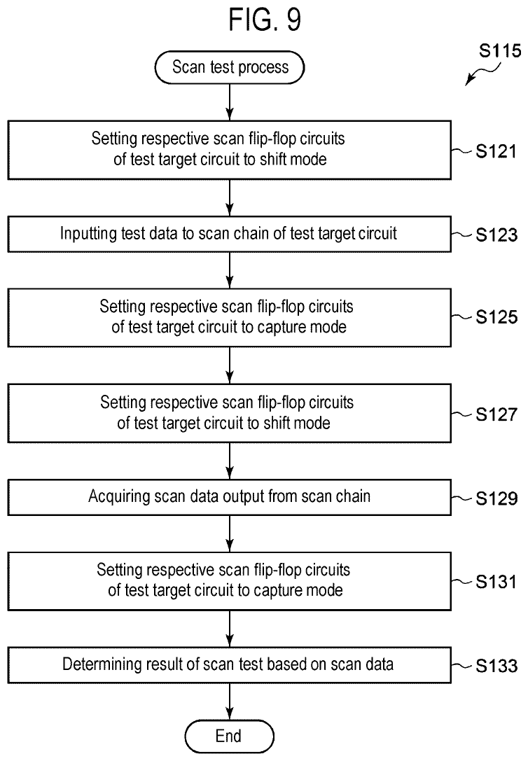

FIG. 9 is a flowchart showing an example of a flow of the scan test process (S115) according to the first embodiment.

First, the test controller 146 sets each of the scan flip-flop circuits of the test target circuit 100 to the shift mode (S121). As a result, the scan chain is formed by the plurality of scan flip-flop circuits of the test target circuit 100. Next, the test controller 146 inputs the test data D_{TEST} to the scan chain of the test target circuit 100 (S123).

Next, the test controller 146 sets each of the scan flip-flop circuits of the test target circuit 100 to the capture mode (S125). At this time, for example, the scan flip-flop circuits 126 capture the output signal S_{NOR} of the NOR circuit 128. Next, the test controller 146 sets each of the scan flip-flop circuits of the test target circuit 100 to the shift mode (S127).

Next, the determiner 148 acquires the scan data D_{SCAN} output from the scan chain (S129). Next, the test controller 146 sets each of the scan flip-flop circuits of the test target circuit 100 to the capture mode (S131). Next, the determiner 148 determines the result of the scan test based on the scan data D_{SCAN} acquired in S129 (S133).

The configuration and operation of the semiconductor integrated circuit 1 according to this embodiment have been described above. According to the semiconductor integrated circuit 1 according to this embodiment, the test controller 146 executes the scan test in the test target circuit 100 in response to the signal requesting the execution of the scan test being transmitted to the semiconductor integrated circuit 1 when the analog circuit is in the active state. In addition, while the scan test is being executed, the second holder 170 holds the output signal S_{OUT1} after the signal requesting the execution of the scan test is transmitted to the semiconductor integrated circuit 1 and before the scan test begins, and outputs the held output signal S_{OUT2} so that the analog circuit may maintain the active state.

According to this configuration, by using the output signal S_{OUT2} output from the second holder 170, it is possible to continue the operation of the analog circuit even while the scan test is being executed on the test target circuit 100. Further, when the semiconductor integrated circuit 1 is the PMIC as in this embodiment, it is possible to perform the scan test while keeping the primary power supply turned on, and it is possible to reliably ensure functional safety while maintaining the operation of the analog circuit.

### Second Embodiment

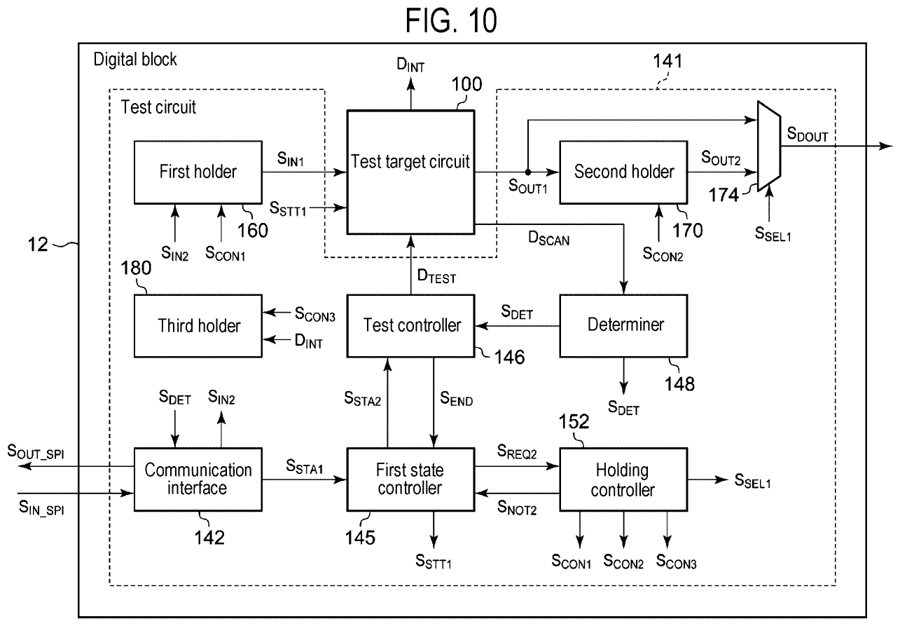

FIG. 10 is a block diagram of a digital block 12 according to a second embodiment. The digital block 12 according to the second embodiment differs from the digital block 10 according to the first embodiment mainly in that a test circuit 141 further includes a third holder 180 that holds the internal data of the test target circuit 100. A semiconductor integrated circuit according to the second embodiment may have a configuration similar to that of the analog block 20 according to the first embodiment.

The first state controller 145 according to this embodiment may transmit, to a holding controller 152, a request signal S_{REQ2}, which requests that the input signal S_{IN2} be held by the first holder 160, the output signal S_{OUT1} be held by the second holder 170, and the internal data D_{INT} of the test target circuit 100 be held by the third holder 180. The internal data D_{INT} of the test target circuit 100 is constituted with the internal signals of the plurality of scan flip-flop circuits which form the scan chain of the test target circuit 100.

The holding controller 152 according to the present embodiment may further generate a control signal S_{CON3} for controlling the holding of data by the third holder 180. When the first holder 160, the second holder 170, and the third holder 180 have completed the holding of the signal or data, the third holder 180 may transmit a signal S_{NOT2} notifying the first state controller 145 of the completion of the holding of the signal or data.

The third holder 180 includes a plurality of flip-flop circuits. The third holder 180 may include a static random-access memory (SRAM) or the like as necessary, for example, when the amount of data to be held is large. In the case where the SRAM is used, the third holder 180 may be provided outside the semiconductor integrated circuit.

The third holder 180 acquires internal data D_{INT} corresponding to the output signal S_{OUT1} held by the second holder 170 from the scan chain and holds the acquired internal data D_{INT}.

The internal data D_{INT} corresponding to the output signal S_{OUT1} is internal data D_{INT} constituted with the internal signals of the test target circuit 100 when the output signal S_{OUT1} is generated. The internal data D_{INT} is data available after the signal requesting the execution of the scan test is transmitted to the semiconductor integrated circuit and before the scan test begins. The third holder 180 continues to hold the internal data D_{INT} while the scan test is being executed.

The internal data held by the third holder 180 is returned to the scan chain after the scan test is completed. Thus, the internal state of the test target circuit 100 may be restored to the state before the scan test began. As a result, the test target circuit 100 may generate an appropriate output signal S_{OUT1} in response to the input signal S_{IN1}.

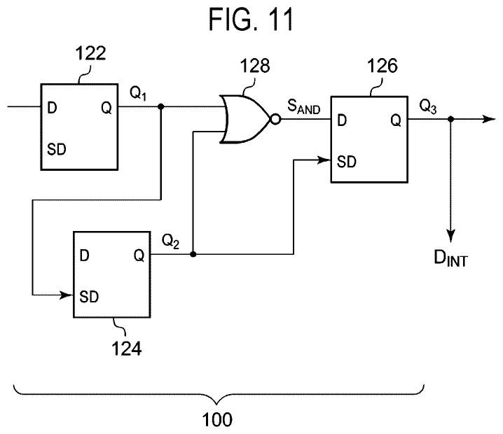

FIG. 11 is a diagram for explaining a process in which the third holder 180 according to the second embodiment acquires the internal data D_{INT} of the test target circuit 100 and a process in which the third holder 180 returns the internal data D_{INT} to the test target circuit 100.

When the third holder 180 acquires the internal data D_{INT} of the test target circuit 100, each of the scan flip-flop circuits 122, 124, and 126 is in the shift mode and forms the scan chain. When the scan chain is formed, the output signals Q₁ to Q₃ of the scan flip-flop circuits 122, 124, and 126 are output sequentially from the output terminal of the scan flip-flop circuit 126 and are held by the third holder 180 as the internal data D_{INT}.

When returning the internal data D_{INT} held by the third holder 180 to the test target circuit 100, the held internal data D_{INT} is input from the scan data input terminal of the scan flip-flop circuit 122 in a state in which the scan flip-flop circuits 122, 124, and 126 form the scan chain. Specifically, the output signal Q₃, the output signal Q₂, and the output signal Q₁ constituting the scan data D_{INT} are input in the named order from the scan data input terminal of the scan flip-flop circuit 122, so that the internal data D_{INT} is returned to the test target circuit 100.

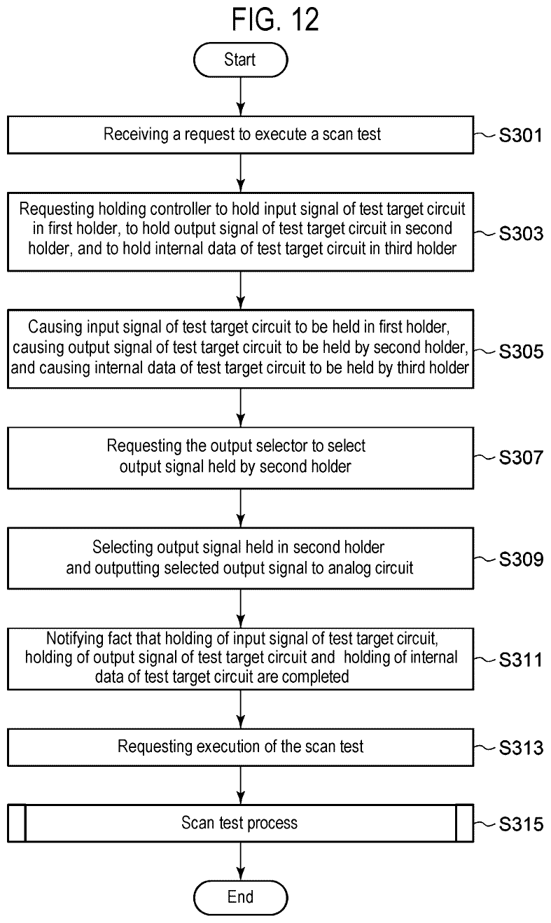

FIG. 12 is a flowchart showing an example of a process until the scan test is executed in the digital block 12 according to the second embodiment. When this process starts, all the analog circuits are assumed to be in the active state. Further, when this process starts, the test target circuit 100, the first holder 160, the second holder 170, and each of the scan flip-flop circuits of the test target circuit 100 are assumed to operate in the capture mode, and the output selector 174 is assumed to have selected the output signal S_{OUT1} generated by the test target circuit 100.

First, the communication interface 142 receives a request to execute the scan test (S301). Next, in response to the communication interface 142 receiving the request for the scan test, the first state controller 145 requests the holding controller 152 to hold the input signal S_{IN2} of the test target circuit 100 in the first holder 160, to hold the output signal S_{OUT1} of the test target circuit 100 in the second holder 170, and to hold the internal data D_{INT} of the test target circuit 100 in the third holder 180 (S303). Next, the holding controller 152 holds the input signal S_{IN2} of the test target circuit 100 in the first holder 160, to hold the output signal S_{OUT1} of the test target circuit 100 in the second holder 170, and to hold the internal data D_{INT} of the test target circuit 100 in the third holder 180 (S305).

Next, the holding controller 152 requests the output selector 174 to select the output signal S_{OUT2} held by the second holder 170 (S307). Subsequently, the output selector 174 selects the output signal S_{OUT2} held by the second holder 170, and outputs the selected output signal S_{DOUT} to the analog circuit (S309).

Next, the holding controller 152 notifies the first state controller 145 that the holding of the input signal S_{IN2} of the test target circuit 100, the holding of the output signal S_{OUT1} of the test target circuit 100, and the holding of the internal signal D_{INT} of the test target circuit 100 have been completed (S311). Next, the first state controller 145 requests the test controller 146 to execute a scan test (S313). Next, the scan test process is performed (S315). The scan test process (S315) is substantially the same as the scan test process (S115) according to the first embodiment, and therefore a description thereof will be omitted here.

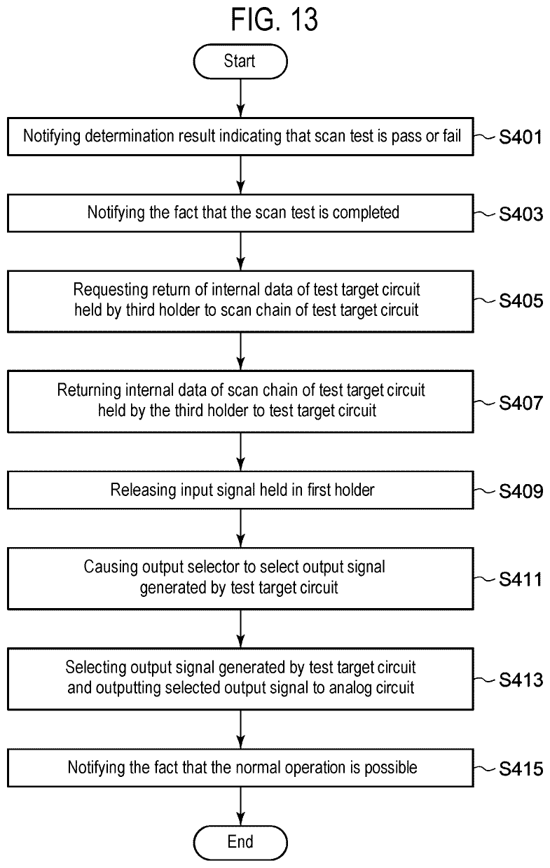

FIG. 13 is a flowchart showing an example of a process until the operation of the digital block 12 returns to the normal operation after the scan test is executed in the digital block 12 according to the second embodiment.

When the scan test process (S315) is completed, the determiner 148 notifies the test controller 146 of the determination result indicating that the scan test is pass or fail (S401). Next, the test controller 146 notifies the first state controller 145 that the scan test has been completed (S403).

Next, the first state controller 145 requests the holding controller 152 to return the internal data D_{INT} of the test target circuit 100 held by the third holder 180 to the scan chain of the test target circuit 100 (S405). Next, the holding controller 152 returns the internal data D_{INT} of the scan chain of the test target circuit 100 held by the third holder 180 to the test target circuit 100 (S407).

Thereafter, processes of S409 to S415 are carried out. Since these processes are substantially the same as the processes of S209 to S215 in the first embodiment, a description thereof will be omitted here.

The configuration and operation of the digital block 12 according to the second embodiment have been described above. According to the digital block 12 according to this embodiment, the third holder 180 acquires the internal data D_{INT} corresponding to the output signal S_{OUT1} held by the second holder 170 from the scan chain, and holds the acquired internal data D_{INT}. The internal data D_{INT} held by the third holder 180 is returned to the scan chain after the scan test is completed.

According to this configuration, the test target circuit 100 may be restored by merely returning the internal data held by the third holder 180 to the scan flip-flop circuits forming the scan chain. Therefore, since there is no need execute a startup process by the test target circuit 100 after the scan test is completed as in the first embodiment, it is possible to restore the test target circuit 100 at a high speed.

### (First Modification)

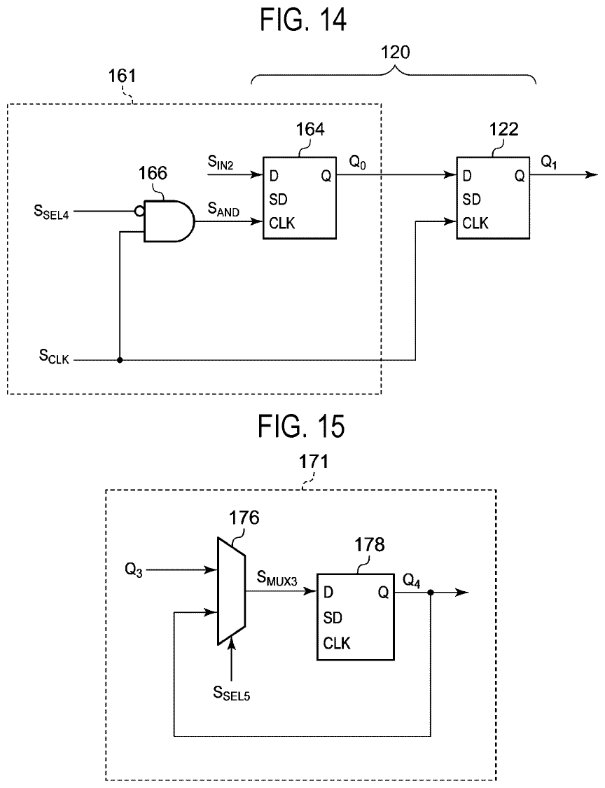

FIG. 14 is a block diagram for explaining a first holder 161 according to a first modification. The first holder 161 according to the first modification may be provided in a digital block in place of the first holder 160 according to the above-described embodiments. As shown in FIG. 14, the first holder 161 according to the first modification includes a signal holding circuit 164 and an AND circuit 166, which are constituted with scan flip-flop circuits that do not contribute to the scan chain of the test target circuit 100.

An inverted selection signal S_{SEL4} is input to a first input terminal of the AND circuit 166, and a clock signal S_{CLK} common to other scan flip-flop circuits (e.g., the scan flip-flop circuit 122 and the like) is input to a second input terminal of the AND circuit 166. An output signal S_{AND} of the AND circuit 166 is input to a clock signal input terminal of the signal holding circuit 164. The selection signal S_{SEL4} may be generated by the holding controllers 150 and 152.

When the selection signal S_{SEL4} is low, the output signal S_{AND} of the AND circuit 166 becomes the clock signal S_{CLK}. When the selection signal S_{SEL4} is high, the output signal S_{AND} of the AND circuit 166 becomes a signal that has no rising and falling edges, specifically, a low signal. The signal holding circuit 164 holds the input signal S_{IN} by receiving the signal (output signal S_{AND}) that has no rising and falling edges at the clock input terminal while the scan test is being executed.

### (Second Modification)

FIG. 15 is a block diagram of a second holder 171 according to a second modification. The second holder 171 according to the second modification may be provided in a digital block in place of the second holder 170 according to the above-described embodiment. As shown in FIG. 15, the second holder 171 according to the second modification includes a multiplexer 176 and a signal holding circuit 178 constituted with scan flip-flop circuits that do not contribute to the scan chain.

The multiplexer 176 selects one of the output signal Q₄ of the signal holding circuit 178 and the output signal Q₃ generated by the test target circuit 100, and inputs the selected signal S_{MUX3} to the data input terminal of the signal holding circuit 178. By selecting the output signal Q₄ of the signal holding circuit 178 while the scan test is being executed, the multiplexer 176 causes the output signal Q₃ generated by the test target circuit 100 to be held by the signal holding circuit 178 in the capture mode. For example, the signal selected by the multiplexer 176 may be determined according to a selection signal S_{SEL5} generated by the holding controllers 150 and 152.

### (Third Modification)

In the above-described embodiment, there has been described an example in which the communication interface 142 is not subject to the scan test. However, the communication interface 142 may be a digital circuit that is subject to the scan test. In other words, the test target circuit may include a communication interface.

### (Fourth Modification)

The processes described with reference to the flowcharts may be executed in different orders as necessary, and multiple processes may be executed in parallel.

The embodiments according to the present disclosure have been described using specific terms, but this description is merely an example to aid understanding and does not limit the scope of the present disclosure or the claims, and the scope of the present disclosure is defined by the claims. In addition to the embodiments, embodiments, examples, and modifications not described herein are also included in the scope of the present disclosure. For example, one or more elements of one embodiment may be combined with one or more elements of another embodiment.

### (Supplementary Note)

The technique disclosed in this specification may be understood in one aspect as follows.

### (Item 1)

A semiconductor integrated circuit includes:
a test target circuit, which is a digital circuit to be subjected to a scan test, configured to generate an output signal for controlling an operation of an analog circuit in response to an input signal;
a test controller configured to control the scan test in the test target circuit; and
a holder configured to hold the output signal,
wherein, when the analog circuit is in an active state, the test controller executes the scan test on the test target circuit in response to a signal requesting execution of the scan test being transmitted to the semiconductor integrated circuit, and
wherein, while the scan test is being executed, the holder holds the output signal available after the signal requesting the execution of the scan test is transmitted to the semiconductor integrated circuit and before the scan test begins, and outputs the held output signal so as to keep the analog circuit in the active state.

### (Item 2)

In the semiconductor integrated circuit of Item 1 above, the holder includes a first holder configured to hold the input signal and a second holder configured to hold the output signal, and
the first holder holds the input signal corresponding to the output signal held by the second holder while the scan test is being executed.

### (Item 3)

In the semiconductor integrated circuit of Item 2 above, the test target circuit includes a plurality of scan flip-flop circuits and logic circuits which form a scan chain,
each of the plurality of scan flip-flop circuits has a test data input terminal to which test data for the scan test is input and a normal data input terminal to which normal data different from the test data is input, and is configured to be switchable between a first mode in which the normal data input terminal is in a valid state and the test data input terminal is in an invalid state, and a second mode in which the normal data input terminal is in an invalid state and the test data input terminal is in a valid state, and
each of the first holder and the second holder is constituted with a scan flip-flop circuit that does not contribute to the scan chain.

### (Item 4)

In the semiconductor integrated circuit of Item 3 above, the second holder includes a signal holding circuit constituted with the scan flip-flop circuit that does not contribute to the scan chain, and
the signal holding circuit is provided so that the output signal is input to the normal data input terminal and no data is input to the test data input terminal, and is configured to hold the output signal in response to switching from the first mode to the second mode.

### (Item 5)

In the semiconductor integrated circuit of Item 3 above, the second holder includes a signal holding circuit constituted with the scan flip-flop circuit that does not contribute to the scan chain, and a multiplexer configured to select one of an output signal of the signal holding circuit and the output signal generated by the test target circuit and input the selected signal to a data input terminal of the signal holding circuit, and
while the scan test is being executed, the multiplexer selects the output signal of the signal holding circuit such that the output signal generated by the test target circuit is held by the signal holding circuit in the first mode.

### (Item 6)

In the semiconductor integrated circuit of any one of Items 3 to 5 above, the first holder includes a multiplexer having two input terminals and a signal holding circuit constituted with the scan flip-flop circuit that does not contribute to the scan chain, and
the multiplexer is provided so that the input signal is input to a first input terminal of the two input terminals and an output signal of the signal holding circuit is input to a second input terminal of the two input terminals, and while the scan test is being executed, the multiplexer selects the output signal of the signal holding circuit such that the output signal is held by the signal holding circuit in the first mode.

### (Item 7)

In the semiconductor integrated circuit of any one of Items 3 to 5 above, the first holder includes a signal holding circuit constituted with the scan flip-flop circuit that does not contribute to the scan chain, and
while the scan test is being executed, when a signal having no rising and falling edges is input to a clock input terminal of the signal holding circuit, the signal holding circuit holds the input signal.

### (Item 8)

The semiconductor integrated circuit of any one of Items 1 to 7 above further includes:
an output selector configured to select one of the output signal generated by the test target circuit and the output signal held by the holder, and output the selected signal, and
wherein, while the scan test is being executed, the output selector selects the output signal held by the holder.

### (Item 9)

The semiconductor integrated circuit of any one of Items 1 to 8 above further includes:
a communication interface configured to receive the signal requesting the execution of the scan test, and
the test target circuit includes the communication interface.

### (Item 10)

The semiconductor integrated circuit of any one of Items 1 to 9 above further includes:
a state controller configured to control a state of the test target circuit,
wherein the state controller causes the test target circuit to execute a predetermined process so that the test target circuit is capable of generating the output signal for keeping the analog circuit in the active state after the scan test is completed.

### (Item 11)

The semiconductor integrated circuit of any one of Items 3 to 7 above further includes:
a third holder configured to hold internal data of the test target circuit,
wherein the internal data is constituted with internal signals of the plurality of scan flip-flop circuits forming the scan chain,
wherein the third holder acquires internal data corresponding to the output signal held by the second holder from the scan chain, and holds the acquired internal data, and
wherein after the scan test is completed, the internal data held by the third holder is returned to the scan chain.

### (Item 12)

The semiconductor integrated circuit of any one of Items 1 to 11 above further includes:
a determiner configured to determine whether or not a result of the scan test is pass or fail; and
a communication interface configured to transmit a determination result indicating that the result of the scan test is fail when the determiner determines that the result of the scan test is fail.

### (Item 13)

In the semiconductor integrated circuit of any one of Items 1 to 12 above, the analog circuit constitutes a DC voltage converter, and
the active state is a state in which the DC voltage converter outputs a predetermined voltage.

While certain embodiments have been described, these embodiments have been presented by way of example only, and are not intended to limit the scope of the disclosures. Indeed, the embodiments described herein may be embodied in a variety of other forms. Further, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor integrated circuit, comprising:
a test target circuit, which is a digital circuit to be subjected to a scan test, configured to generate an output signal for controlling an operation of an analog circuit in response to an input signal;
a test controller configured to control the scan test in the test target circuit; and
a holder configured to hold the output signal,
wherein, when the analog circuit is in an active state, the test controller executes the scan test on the test target circuit in response to a signal requesting execution of the scan test being transmitted to the semiconductor integrated circuit, and
wherein, while the scan test is being executed, the holder holds the output signal available after the signal requesting the execution of the scan test is transmitted to the semiconductor integrated circuit and before the scan test begins, and outputs the held output signal so as to keep the analog circuit in the active state.

2. The semiconductor integrated circuit of claim 1, wherein the holder includes a first holder configured to hold the input signal and a second holder configured to hold the output signal, and
wherein the first holder holds the input signal corresponding to the output signal held by the second holder while the scan test is being executed.

3. The semiconductor integrated circuit of claim 2, wherein the test target circuit includes a plurality of scan flip-flop circuits which forms a scan chain, and logic circuits,
wherein each of the plurality of scan flip-flop circuits has a test data input terminal to which test data for the scan test is input and a normal data input terminal to which normal data different from the test data is input, and is configured to be switchable between a first mode in which the normal data input terminal is in a valid state and the test data input terminal is in an invalid state, and a second mode in which the normal data input terminal is in an invalid state and the test data input terminal is in a valid state, and
wherein each of the first holder and the second holder is constituted with a scan flip-flop circuit that does not contribute to the scan chain.

4. The semiconductor integrated circuit of claim 3, wherein the second holder includes a signal holding circuit constituted with the scan flip-flop circuit that does not contribute to the scan chain, and
wherein the signal holding circuit is provided so that the output signal is input to the normal data input terminal and no data is input to the test data input terminal, and is configured to hold the output signal in response to switching from the first mode to the second mode.

5. The semiconductor integrated circuit of claim 3, wherein the second holder includes a signal holding circuit constituted with the scan flip-flop circuit that does not contribute to the scan chain, and a multiplexer configured to select one of an output signal of the signal holding circuit and the output signal generated by the test target circuit and input the selected signal to a data input terminal of the signal holding circuit, and
wherein, while the scan test is being executed, the multiplexer selects the output signal of the signal holding circuit such that the output signal generated by the test target circuit is held by the signal holding circuit in the first mode.

6. The semiconductor integrated circuit of claim 3, wherein the first holder includes a multiplexer having two input terminals and a signal holding circuit constituted with the scan flip-flop circuit that does not contribute to the scan chain, and
wherein the multiplexer is provided so that the input signal is input to a first input terminal of the two input terminals and an output signal of the signal holding circuit is input to a second input terminal of the two input terminals, and while the scan test is being executed, the multiplexer selects the output signal of the signal holding circuit such that the output signal is held by the signal holding circuit in the first mode.

7. The semiconductor integrated circuit of claim 3, wherein the first holder includes a signal holding circuit constituted with the scan flip-flop circuit that does not contribute to the scan chain, and
wherein, while the scan test is being executed, when a signal having no rising and falling edges is input to a clock input terminal of the signal holding circuit, the signal holding circuit holds the input signal.

8. The semiconductor integrated circuit of claim 3, further comprising:
an output selector configured to select one of the output signal generated by the test target circuit and the output signal held by the holder, and output the selected signal,
wherein, while the scan test is being executed, the output selector selects the output signal held by the holder.

9. The semiconductor integrated circuit of claim 1, further comprising:
a communication interface configured to receive the signal requesting the execution of the scan test,
wherein the test target circuit includes the communication interface.

10. The semiconductor integrated circuit of claim 1, further comprising:
a state controller configured to control a state of the test target circuit,
wherein the state controller causes the test target circuit to execute a predetermined process so that the test target circuit is capable of generating the output signal for keeping the analog circuit in the active state after the scan test is completed.

11. The semiconductor integrated circuit of claim 3, further comprising:
a third holder configured to hold internal data of the test target circuit,
wherein the internal data is constituted with internal signals of the plurality of scan flip-flop circuits forming the scan chain,
wherein the third holder acquires internal data corresponding to the output signal held by the second holder from the scan chain, and holds the acquired internal data, and
wherein, after the scan test is completed, the internal data held by the third holder is returned to the scan chain.

12. The semiconductor integrated circuit of claim 1, further comprising:
a determiner configured to determine whether or not a result of the scan test is pass or fail; and
a communication interface configured to transmit a determination result indicating that the result of the scan test is fail when the determiner determines that the result of the scan test is fail.

13. The semiconductor integrated circuit of claim 1, wherein the analog circuit constitutes a DC voltage converter, and
wherein the active state is a state in which the DC voltage converter outputs a predetermined voltage.
